(19) United States
(12) Patent Application Publication
(10) Pub. No.: US 2007/0054501 A1
(43) Pub. Date: Mar. 8, 2007

(54) Process for modifying dielectric materials

(75) Inventors: April J. Carman, Richland, WA (US); Thomas S. Zemanian, Richland, WA (US); Glen E. Fryxell, Richland, WA (US); Daniel J. Gasper, Richland, WA (US)

Correspondence Address: BATTELLE MEMORIAL INSTITUTE;ATTN: IP SERVICES, K1-53, P. O. BOX 999, RICHLAND, WA, 99352, US

(73) Assignee: Battelle Memorial Institute, Richland, WA (US)

(21) Appl. No.: 11/210,546

(22) Filed: Aug. 23, 2005

(51) Int. Cl. H01L 21/31

(52) U.S. Cl. 438/781

(57) ABSTRACT

The invention relates to a process for modifying materials including, e.g., dielectric materials associated with electronic substrates, semiconductor chips, wafers, and the like, damaged by fabrication processes such as plasma etch processing. The described method improves structural integrity as measured, e.g., by Young's Modulus, as well as hydrophobicity, as measured, e.g., by contact angles at the liquid/surface interface.

### FIELD OF THE INVENTION

The present invention relates generally to a method for repairing and/or modifying low-k dielectric materials. More particularly, the invention is a method for repairing and/or modifying low-k dielectric materials damaged during (e.g., plasma etch) processing. The invention finds application in the fabrication and repair of semiconductor substrates, films, and/or materials, including wafers and chips.

### BACKGROUND OF THE INVENTION

Semiconductor chips used in a multitude of electronic devices are composite substrates fabricated from materials including dielectrics and organosilicate films. To minimize “cross-talk” between neighboring conductive traces in solid state electronic devices, these materials are made porous. Ultrafine feature sizes and high performance requirements in combination with the aforementioned porous nature of the devices have resulted in mechanically weaker low-k dielectrics and silicon-level interconnects as compared to previous-generation materials. The inherently weaker nature of the low-k dielectric materials can pose significant challenges to downstream electronic-packaging processes and materials, facts that are being recognized as industry-wide issues. Most of the problems that show up during low-k assembly can be traced to typically lower interfacial-adhesion strength in a silicon stackup, and weaker bulk-mechanical and fracture-strength properties. These weaknesses are well known in the industry and many research efforts are under way in assembly sites worldwide to compensate for them or to make them more tolerable.

However, processing such as plasma etching employed during patterning of these porous substrates introduces surface defects and changes in local surface chemistry. Defects including replacement of terminal methyl functional groups within the organosilicate matrix with hydroxyl groups invite absorption of water used during processing. Such surface changes (i) increase the material dielectric constant, (ii) increase the capacitive “cross-talk” in the material, and (iii) limit the number of neighboring traces that can be placed in proximity in or on the material. While the fabrication industry does not yet currently engage in repair of (e.g., plasma) damaged substrates, interest in such technology has increased. Current research studies have investigated use of silylating agents such as trimethylchlorosilane (TMCS) and hexamethyldisilzane (HMDS) as capping agents which cap hydroxyl groups with trimethylsilyl terminal groups. However, to date, none of the investigated agents restore lost mechanical strength of the matrix materials. Accordingly, a need exists for new processes that repair and/or modify low-k dielectric materials damaged during processing restoring functionality and structural integrity. In particular, interest is in systems and processes that minimize use of chemistries employing aqueous media and/or processes that employ extensive baking to remove both water and chemical constituents.

### SUMMARY OF THE INVENTION

In one aspect, a process is disclosed for modifying and/or repairing a damaged dielectric material, comprising: contacting a damaged dielectric material having damage sites with a near-critical or supercritical fluid comprising an alkoxysilane silylating agent whereby the damaged sites are modified substantially repairing the sites and material contacted by the agent.

In another aspect, a method is disclosed for modifying and/or repairing dielectric materials, comprising the steps: providing a dielectric material having sites characterized by hydrophilic damage; providing a near-critical or supercritical fluid comprising an alkoxysilane silylating agent; and contacting the material with the fluid, whereby the sites are cross-linked and rendered hydrophobic modifying the material substantially repairing the hydrophilic damage of the material.

In an embodiment, the dielectric material is selected from inorganic, organic, hybrid, interlayer, spin-on, or combinations thereof.

In an embodiment, the near-critical, or supercritical fluid comprises a member selected from Freon®, carbon dioxide, noble gases, nitrogen, unsaturated aliphatic hydrocarbons, alkanes, carboxylic acids, sulfurhexafluoride, ammonia, alcohols, methyl amines, derivatives thereof, or combinations thereof.

In an embodiment, the near-critical, or supercritical fluid comprises carbon dioxide.

In an embodiment, the alkoxysilane silylating agent is selected from n-propyltrimethoxysilane, n-propyltriethoxysilane, ethyltrimethoxysilane, ethyltriethoxysilane, methyltrimethoxysilane, methyltriethoxysilane, dimethyldimethoxysilane, derivatives thereof, or combinations thereof.

In another embodiment, the alkoxysilane silylating agent is n-propyltrimethoxysilane (n-PTMS).

In an embodiment, damaged sites are hydrophilic damage sites characterized by hydroxyl-terminated (hydrophilic) functional groups that are rendered hydrophobic by action of the silylating agent substantially restoring the hydrophobicity of the material thereby repairing the material contacted by the agent.

In another embodiment, repairing comprises chemically capping hydrophilic damage sites comprising terminal hydroxyl(—OH) functional groups with an alkoxysilane silylating agent comprising hydrophobic alkyl groups, whereby the alkoxysilane silylating agent cross-links strengthening the material substantially restoring the structural integrity of the material.

In another embodiment, repairing comprises chemically capping terminal hydroxyl(—OH) functional groups with alkoxysilane silylating agent substantially restoring the dielectric value of the material and whereby cross-linking of the silylating agent substantially restores the structural integrity of the material.

In an embodiment, repairing comprises substantially restoring one or more of dielectric values, structural integrity, carbon content, hydrophobicity, and interfacial surface water contact angle of the material thereby substantially repairing the material.

In another embodiment, the dielectric value of the material is restored to a value less than about 3.2.

In another embodiment, cross-linking yields a Young's modulus value in the material of greater than or equal to about 14.3 MPa.

In another embodiment, repairing further comprises increasing the surface hydrophobicity.

In another embodiment, repairing further comprises substantially restoring the hydrophobicity of the material by substantially restoring the surface interfacial water contact angle of the material.

In another embodiment, the interfacial water contact angle is in the range from about 80 degrees to about 95 degrees or better.

In another embodiment, repairing further comprises substantially restoring the carbon content of the material.

In another embodiment, carbon content is increased to a value in the range from about 3% to about 15% (mole-fraction basis).

In another embodiment, alkoxysilane is selected from the group consisting of n-propyltrimethoxysilane, n-propyltriethoxysilane, ethyltrimethoxysilane, ethyltriethoxysilane, methyltrimethoxysilane, methyltriethoxysilane, dimethyldimethoxysilane, derivatives thereof, or combinations thereof.

In another embodiment, the near-critical or supercritical fluid comprises a member selected from the group consisting of Freon®, carbon dioxide, noble gases, nitrogen, alkanes, carboxylic acids, sulfurhexafluoride, ammonia, alcohols, methyl amines, derivatives thereof, or combinations thereof.

In another embodiment, the fluid has a density above the critical density for the fluid.

In another embodiment, the fluid comprises carbon dioxide at a pressure in the range from about 800 psi to about 10,000 psi and a temperature in the range from about −40° C. to about 300° C.

In another embodiment, the fluid further comprises a modifier reagent.

In another embodiment, the modifier reagent is a carboxylic acid selected from acetic acid and/or formic acid.

In another embodiment, the modifier is an alcohol selected from methanol, ethanol, isopropanol, or combinations thereof.

In another embodiment, the dielectric material is pre-cleaned prior to contacting with alkoxysilane silylating agent in the near-critical or supercritical fluid.

### BRIEF DESCRIPTION OF THE DRAWINGS

A more complete appreciation of the invention will be readily obtained by reference to the following description of the accompanying drawing in which like numerals in different figures represent the same structures or elements.

FIG. 1 illustrates use of surface interfacial water contact angle as a measure of damage (e.g., hydrophilic damage) associated with a dielectric substrate, film, and/or material.

FIG. 2 illustrates a reaction vessel and system of a flow-through design for modifying and/or repairing dielectric substrates, films, and/or materials, according to an embodiment of the invention.

### DETAILED DESCRIPTION OF THE INVENTION

While the present invention is described herein with reference to the preferred embodiments thereof, it should be understood that the invention is not limited thereto, and various alternatives in form and detail may be made therein without departing from the spirit and scope of the invention.

The present invention relates generally to a method for repairing and/or modifying low-k dielectrics, including, but not limited to, e.g., substrates, films, and/or materials. More particularly, the invention is a method for repairing and/or modifying low-k dielectrics damaged by (e.g., plasma etch) processing. The invention finds application in the manufacturing and repair of semiconductor substrates, integrated circuits, semiconductor chips and wafers, interconnects, and the like.

The term “Low-k dielectric” as the term is used herein refers to substrates, films, and/or materials having a dielectric constant (k) below about 3.9 (the k of SiO₂). Low-k dielectrics include, but are not limited to, inorganic (non-carbon or silicon-based) dielectrics, organic (carbon-based) dielectrics, hybrid (inorganic-organic) dielectrics, or combinations thereof. Low-k dielectrics find use as, e.g., inter-layer (or inter-level) dielectrics (ILD) and spin-on dielectrics (SOD) in semiconductor devices, but are not limited thereto. Materials and uses listed herein are intended to be representative, not limiting.

Inorganic low-k dielectrics include, but are not limited to, e.g., inorganic oxides, porous oxides, oxide-like materials, glasses, silicates, or other inorganic materials having dielectric (k) values in the range from about k=1.3 to about k=3.9. Representative inorganic low-k dielectrics include, but are not limited to, e.g., NANOGLASS® (NanoPore, Inc., Albuquerque, N. Mex.), Fluorinated Silicate Glasses (FSG) (Intel, Santa Clara, Calif., USA), and like materials.

Organic low-k dielectrics include, but are not limited to, e.g., polar and non-polar polymers, benzo-cyclo-butene (Dow Chemical Co., Midland, Mich., USA), oxazole resins, aromatic ethers such as SiLK® (Dow Chemical Co., Midland, Mich., USA), Fluorinated Arylene Ethers also known as FLARE® (Honeywell Morris Township, N.J., USA), polyimides, cyclic olefins such as polyquinoline, conformal coatings such as parylene® (Parylene Coating Services Inc., Katy, Tex., USA), poly tetrafluoro ethylenes (PTFEs), or like materials.

Hybrid dielectrics comprise the family of inorganic-organic dielectric materials, including, but not limited to, e.g., organic silicate glasses (OSGs), 3-methylsilanes, silicon oxycarbide films (SiOCH), Hidrido-Organo-Siloxane Polymers also known as HOSP® (Honeywell, Morris Township, N.J., USA), methyl siloxane polymers such as Accuglass® (Honeywell, Morris Township, N.J., USA), silsesquioxanes (SSQ) including, e.g., hydrogen-silsesquioxane (HSSQ) and methyl-silsesquioxane (MSSQ), perfluorocyclobutane (PFCB), poly aryl ethers (PAE's), siloxanes (saturated silicon-oxygen hydrides), and like materials.

The term “damage” and/or “damaged” as the terms are used herein refer to structural and/or chemical changes to dielectric substrates, films, and/or materials characterized by one or more of the following relative to an undamaged or “as-received” control: (i) decreases in carbon content to less than about 3% (mole fraction basis), (ii) increases in dielectric (k) value to greater than about k=3.2, (iii) increased hydrophilicity (decreased hydrophobicity) as assessed by surface interfacial water contact angles below about 45 degrees, and/or (iv) decreased structural integrity and/or strength as assessed by decreases in Young's Modulus values to below about 10 MPa. Damage indicators described herein are intended to be representative, not exclusive.

The term “repair” and/or “repaired” as the terms are used herein refer to structural and/or chemical changes of dielectric substrates, films, and/or materials relative to damaged controls characterized by one or more of the following: (i) increases in carbon content values in the range from about 3% to about 15% or better, (ii) dielectric (k) values of below about k=3.2 or lower, (iii) increases in, or restoration of, hydrophobicity (decreases in hydrophilicity) as assessed, e.g., by increases in surface interfacial water contact angles to values in the range from about 800 to about 950 or better, and/or (iv) increases in, or restoration of, structural integrity and/or strength of the dielectric substrate, film, and/or material as assessed, e.g., by Young's Modulus values greater than or equal to about 14.3 MPa. Again, indicators described herein are intended to be representative, not exclusive. Other parameters of dielectric substrates, films, and/or materials being treated may likewise be monitored and/or measured in assessing degree of repair as will be selected or understood by those of skill in the art.

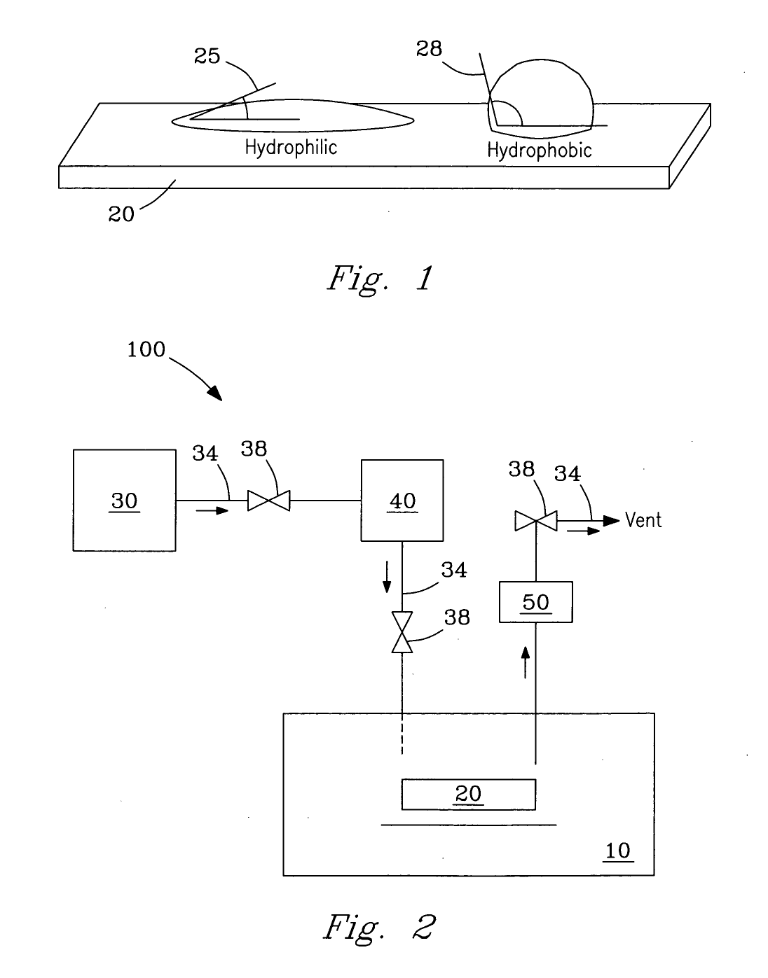

FIG. 1 illustrates use of surface interfacial water contact angle (contact angle) as one measure for assessing degree of damage to, and/or change in state of, dielectric substrates 20, films, and materials, as well as repair thereof. Contact angle at the liquid-solid interface correlates with degree of hydrophilicity (wettability) or hydrophobicity of the substrate, film, and/or material. The greater the damage to the substrate, film, and/or material, the more hydrophilic the material, which correlates with a contact angle 25 at the liquid-solid interface that is less than that measured for an undamaged control. The more pronounced the damage, the greater the difference from the control value. Likewise, successful treatment effecting repair of a dielectric substrate, film, and/or material increases the hydrophobicity at the liquid-solid interface correlating with a contact angle 28 greater than that measured for the damaged substrate 20, film, and/or material. Difference between the measured values relative to controls approaches zero as repair is effected, and can thus be used to assess effectiveness of the repair and/or treatment.

### Solvents

Solvents selected for use are fluids from the group of compressible or liquefied (densified) fluids or gases, near-critical fluids, and supercritical fluids including, but not limited to, Freon®, noble gases, carbon dioxide (CO₂), nitrogen (N₂), unsaturated aliphatic hydrocarbons (e.g., ethylene), alkanes (e.g., ethane, propane, butane), derivatives thereof (e.g., chlorotrifluoroethane, methyl amines, and the like), alcohols, carboxylic acids, sulfurhexafluoride, ammonia, or combinations thereof, wherein the fluid density (ρ) is selected above the critical density (ρ_{c}) for the neat fluid (i.e., ρ>ρ_{c}). The critical density (ρ_{c}) for the neat fluid is given by equation [1]:

$${ρ}_{c} = [ ( \frac{1}{{V}_{c}} ) \times ( M . W . ) ] \qquad [ 1 ]$$

where V_{c} is the critical volume (ml/mol) and M.W. is the molecular weight (g/mol) of the constituent fluid (“Properties of Gases and Liquids”, 3ed., McGraw-Hill, pg. 633).

Carbon dioxide (CO₂) is an exemplary solvent fluid given its useful critical conditions (i.e., T_{c}=31° C., P_{c}=72.9 atm, and a critical density (ρ_{c}) of approximately 0.47 g/mL, CRC Handbook, 71^{st} ed., 1990, pg. 6-49), and low surface tension exerted on pattern features (about 1.2 dynes/cm at 20° C., Encyclopedie Des Gaz”, Elsevier Scientific Publishing, 1976, pg. 338) of electronic substrates, materials, and/or films. Densified CO₂ further exhibits a 100-fold better diffusion compared to aqueous fluids [see, e.g., Chemical Synthesis Using Supercritical Fluids, Philip G. Jessop, Waltner Leitner (eds.), Wiley—VCH, pg. 38] providing for rapid transport of reagents, removal of byproducts, penetration and/or infiltration of the porous matrix of low-k dielectric substrates, films, and/or materials, being modified and/or repaired. In addition, solvents and fluids of the invention are readily recovered following processing of the various materials, substrates, and/or films.

Temperatures for densified CO₂ are selected in the range from about −40° C. to about 300° C. with a pressure up to about 10,000 psi. More particularly, temperatures of densified CO₂ are selected up to about 60° C. with a pressure in the range from about 850 psi to about 3000 psi. Most particularly, temperatures of densified CO₂ are selected in the range from about 20° C. to about 25° C. with a pressure of about 1100 psi and a density exceeding the critical density of pure CO₂ (i.e., ρ_{c}>0.47 g/cc). Suitable temperature and pressure regimes above the critical density may be selected from plots of reduced pressure (Pᵣ) as a function of reduced density (ρᵣ) where the corresponding reduced temperatures (Tᵣ) is identified. In general, densified fluids at supercritical fluid (SCF) conditions need only exceed their critical parameters. Thus, for a CO₂-based system, above a temperature of about 31° C., a pressure for the SCF system need only exceed the critical pressure of CO₂. As will be understood by those of skill in the art, addition of modifiers (e.g., simple alcohols) typically causes an increase in the critical temperature and pressure of the solvent mixture; conditions are adjusted accordingly to maintain, e.g., the near-critical or supercritical conditions. Many temperatures for SCF systems are practicable if the density of the solution mixture is maintained above that needed for solubility, meaning many density increases may be exploited in a densified fluid by effecting changes to pressure and/or temperature in the system. Similar or greater effects can be attained in SCF fluids where higher densities may be exploited as a function of pressure and/or temperature.

### Silylating Agents

Etch processing damages the silica structure of dielectric substrates, materials, and/or films, by replacing surface methyl groups and internal methylene groups with hydroxyl groups resulting in a weakened, more hydrophilic organosilicate structure. Low-k dielectric materials, substrates, and/or films damaged during (e.g., etch) processing are modified and/or repaired in conjunction with various silylating agents which are soluble in the selected near-critical and supercritical fluids. Silylating agents used in conjunction with the invention are selected from the group of alkoxysilanes including, but not limited to, e.g., n-propyltrimethoxysilane, n-propyltriethoxysilane, ethyltrimethoxysilane, ethyltriethoxysilane, methyltrimethoxysilane, methyltriethoxysilane, dimethyldimethoxysilane, derivatives thereof, or combinations thereof. Concentration for alkoxysilane silylating agent is selected in the range from about 0.0001 wt % to about 10 wt %. More particularly, concentration is selected in the range from about 0.0001 wt % to about 5 wt %. Most particularly, concentration is selected in the range from about 0.0001 wt % to about 1 wt %.

In the repair process, alkoxysilanes attach to terminal hydroxyl (—OH) functional groups, which are characteristic of the damaged material. Hydrogen leaves the terminal hydroxyl groups whereby alkoxysilanes bearing hydrophobic alkyl functional groups cap the surface oxygen, simultaneously linking to neighboring surface alkoxysilanes, effectively cross-linking across the hydroxyl defect sites thereby strengthening the dielectric and returning the damaged substrate, film, and/or material to its hydrophobic state. Hydrophobicity of the treated substrate, material, and/or film can be assessed, e.g., by the measured increase in contact angle at the liquid-solid (water/surface) interface of the material, the so-called “interfacial water contact angle”. Cross-linking characteristic of the alkoxysilane silylating agents is further correlated with substantial improvements in, and/or restoration of, e.g., carbon contents, dielectric values, Young's Modulus, and/or other physical properties consistent with the pre-damaged condition, as demonstrated in Examples presented herein. Agents are avoided having potential to generate complex waste products incompatible with selected solvent fluids, including, but not limited to, e.g., trimethylchlorosilane (TMCS) and hexamethyldisilzane (HMDS). For example, HMDS generates ammonia as a byproduct of the silylation reaction which in turn reacts with carbon dioxide producing carbamate species that can further react to form insoluble urea species. In contrast, silylating agents described herein produce byproducts (e.g., alcohols) that are readily soluble in the solvent fluid and easily recovered following processing.

### Substrate and/or Material Preparation

In some cases, improved results (as measured by interfacial water contact angles, dielectric values, structural integrity improvement, cross-linking, and/or other associated factors) for dielectric materials and/or substrates modified and/or repaired in conjunction with the invention may be achieved when substrates and/or materials to be modified and/or repaired are cleaned with a cleaning agent. Cleaning removes etch and/or processing residues and/or other contaminants that may interfere with the critical chemistries (e.g., surface hydration) or other physical processes associated with modification and repair of the dielectric substrates, films, and/or materials. Various approaches have been successfully tested to clean substrates and/or test materials in preparation for modification and/or repair with the alkoxysilane silylating agent. In one approach, substrates and/or test materials are cleaned in conjunction with a near-critical or supercritical surfactant fluid, as described in co-pending application Ser. No. 10/851,380, incorporated herein in its entirety. In another approach, substrates and/or materials are pre-cleaned with a dilute preparation of hydrofluoric acid (HF), followed by rinsing with a pure solvent fluid and drying under inert (e.g., nitrogen) atmosphere. Concentration of HF is variable but is preferably dilute, e.g., 1:1000 (HF:water) by volume with water to minimize potential for etch damage to important structures or pattern features (e.g., vias, trenches, and/or other chip features) of the substrates, films, and/or materials being processed. As will be known by those of skill in the art, changes in critical dimensions (e.g., width, depth) of structures and/or pattern features or other surface phenomenon may be measured in conjunction with, e.g., Transmission Electron Microscopy (TEM) or Scanning Electron Microscopy (SEM) analysis, other chemical and/or instrumental analysis techniques, and/or comparison with substrate and/or material controls. No limitations are intended.

Cleaning and/or rinsing (e.g., pre-cleaning) of substrates and/or materials may be done using any suitable solvent including, but not limited to, alcohols (e.g., methanol, ethanol, isopropanol), carbon dioxide, and aprotic solvents including, but not limited to, cyclohexane, alkanes, ethers, or combinations thereof. Cleaning and/or rinsing of treated, modified, and/or repaired substrates, films, and/or materials may likewise be effected using like solvents. In addition, other chemical reagents known to those of skill in the art for electronic surface processing may be used without limitation including, e.g., ammonium fluoride (NH₄F) or HF.

Modifier reagents (modifiers) including, e.g., water, acetic acid, formic acid, and/or other selected reagents, may be optionally introduced to the solvent fluid to initiate, promote, catalyze, and/or accelerate desired reaction chemistries including, but not limited to, e.g., hydrolysis, polymerization, and/or cross-linking of the alkoxysilane silylating agent, and/or other associated chemistries. Further, modifier reagents including, e.g., methanol, ethanol, isopropanol, and/or other selected reagents, may be optionally introduced to the solvent fluid to promote dissolution of the active reagents in the near-critical or supercritical reaction medium. Concentration of modifiers is selected in the range from about 0.0001 wt % to about 10 wt %. More particularly, concentration is selected in the range from about 0.0001 wt % to about 5 wt %. Most particularly, concentration is selected in the range from about 0.0001 wt % to about 1 wt %. No limitations are intended.

A system for modifying and/or repairing electronic substrates and/or dielectric materials will now be described with reference to FIG. 2.

FIG. 2 illustrates a system 100 for modifying and/or repairing electronic substrates 20 and/or dielectric materials, according an embodiment of the invention. System 100 includes a processing chamber or reactor 10 suitable for operating at selected temperatures and pressures. A selected solvent fluid is introduced to system 100 and reactor 10 from source 30 (e.g., gas cylinder and/or pump). Alkoxysilane silylating agent is introduced from source 40 (e.g., mixing or fluid vessel) to reactor 10 in either of a pure form or a premixed form with the selected solvent fluid. Alternatively, silylating agent may be mixed in transit to reactor 10 as solvent fluid from source 30 flows through source 40. System 100 is equipped with a rupture disk 50 or similar safety or pressure relief component. Elements, components, devices, and/or systems of system 100, including fluid and/or reagent delivery systems are linked via standard conduit 34 or piping 34. Introduction of fluids and reagent constituents to reactor 10 is further effected and/or controlled by opening and/or closing of selected valves 38. No limitations are intended. For example, in other embodiments, source 40 may be disposed so as not to be directly inline with source 30 permitting independent introduction of silylating agent in either premixed or pure form to reactor 10.

In the instant embodiment, operating temperature for reactor 10 is selected in the range from about −40° C. to about 300° C., but is not limited thereto. More particularly, temperature is selected in the range from about 25° C. to about 150° C. Operating pressure for reactor 10 is selected in the range up to about 8,000 psi, but is not limited thereto. Contact time between the dielectric substrate, film, and/or material with the solvent fluid comprising the alkoxysilane silylating agent is selected in the range from about 1 minutes to about 48 hours, but is not limited thereto. More particularly, contact time with the substrate, material, and/or film is selected in the range from about 3 minutes to about 30 minutes, but is not limited thereto.

As will be understood by those of skill in the art, system 100 may comprise any of a number of elements, components, vessels, and/or devices without limitation. For example, pressure and temperature of reactor 10 may be controlled in conjunction with programmable pressure and temperature controller(s) or other like devices and/or systems. In addition, systems and/or devices for pumping, transferring, spraying, delivering, mixing, pressurizing, heating, and/or storing fluids, reagents, and/or solvents of the invention may be used without limitation. For example, in one or more configurations, temperature of reactor 10 is controlled in conjunction with various heating devices and/or systems including, but not limited to, e.g., heaters, boilers, heat exchangers, or like devices. In other embodiments, fluids employed herewith may be collected in waste reservoirs or other containment or collection systems. For example, solvent(s) may be recovered from the waste stream by flash distillation and recovered and/or recycled. Residues and/or wastes in the waste stream may be collected following separation and/or recovery of the solvent fluid. In other configurations, devices and/or systems for transferring, coating, cleaning, rinsing, and/or repairing substrates, materials, and/or films may be coupled within system 100 and/or effected in conjunction with computer-control as will be understood and/or implemented by those of skill in the art. No limitations are intended.

As will be further understood by those of skill in the art, treatment with alkoxysilane silylating agent to repair and/or modify dielectric substrates and/or materials can be coupled with, e.g., pre-treatment cleaning and/or rinsing with various solvents and/or reagent fluids to remove residues, post-treatment rinsing with various solvents and/or fluids to remove process reagents, and/or post-treatment heating (“baking”) to cure substrates or materials. No limitations are intended. For example, post-treatment heating (“baking”) to cure substrates or materials may be done in reactor 10 or in a process chamber separate from, or coupled to, system 100. All configurations as will be contemplated by those of skill in the art are encompassed herein.

The following examples are intended to promote a further understanding of the present invention.

### EXAMPLE 1

Example 1 describes repair of dielectric substrates 20 treated using an alkoxysilane reagent (e.g., n-PTMS) as a function of reactor 10 temperature. Modifier reagents including water and acetic acid were optionally added to initiate, promote, and/or catalyze polymerization and/or cross-linking of the silylating reagent. In exemplary tests, premixing vessel 40 was charged with ˜5 μL of reagent grade n-propyltrimethoxysilane (n-PTMS) (Gelest, Inc., Philadelphia, Pa.) and 10 μL H₂O. Reactor 10 was pressurized with solvent fluid comprising carbon dioxide to a pressure of 2500 psig achieving a concentration for the n-PTMS reagent in the near-critical or supercritical solvent fluid (reagent fluid) of about 0.01 wt %, but is not limited thereto. In other tests, substrates 20 were subjected to n-PTMS reagent (mixed in the solvent fluid) further comprising various modifiers (equal weight percentage). In other tests, substrates 20 were subjected to an optional pre-clean step, as described hereinabove, prior to treatment with alkoxysilane reagent. In other tests, substrates 20 were treated “as received” with alkoxysilane reagent, i.e., absent any pre-clean step. Temperature of reactor 10 for repair of substrates 20 was selected in the range from about 25° C. to about 150° C. Contact time with the reagent fluid including any modifiers was about 30 minutes, but is not limited thereto. All concentrations for n-PTMS and/or modifier reagents were variable. Thus, no limitations are intended. Table 1 lists contact angles, dielectric constants, and carbon contents measured for the dielectric substrate repaired with the n-PTMS reagent as a function of repair temperature.

TABLE 1
Contact angles and dielectric constants measured for damaged dielectrics before
and after repair with n-propyltrimethoxysilane (n-PTMS) silylating agent.

| | | | | | Carbon |
|---|---|---|---|---|---|
| | | | | Dielectric | Content |
| | | Contact Angle*Δ | | Constant | (atomic %) |
| | Treatment** | Before | After | k Δ | ΔΔ |
| Samples | | | | | |
| 1-1 | n-PTMS; | 4.88 ± 0.89° | 89.6 ± 4.4° | 3.16 ± 0.04 | 4.3 ± 0.3 |
| | 40° C.; | | | to | |
| | 2500 psig; | | | 3.46 ± 0.11 | |
| | acetic acid; | | | | |
| 1-2 | n-PTMS; | — | — | 2.93 ± 0.06 | 3.5 ± 0.7 |
| | 70° C.; | | | | to |
| | 2500 psig; | | | | 3.6 ± 0.6 |
| 1-3 | n-PTMS; | — | — | 2.87 ± 0.08 | — |
| | 90° C.; | | | | |
| | 2500 psig; | | | | |
| 1-4 | n-PTMS; | 3.75 ± 0.95° | 92.6 ± 1.3° | 3.04 ± 0.13 | 5.0 ± 0.6 |
| | 110° C.; | | | | to |
| | 2500 psig; | | | | 5.2 ± 0.5 |
| 1-5 | n-PTMS; | 3.56 ± 0.95° | 93.9 ± 1.6° | 3.07 ± 0.05 | — |
| | 130° C.; | | | | |
| | 2500 psig; | | | | |
| 1-6 | n-PTMS; | 4.66 ± 0.53° | 93.3 ± 2.3° | 2.96 ± 0.01 | 7.2 ± 1.1 |
| | 150° C.; | | | | |
| | 2500 psig; | | | | |
| Controls | | | | | |
| A | Undamaged | 97.2° | n/a | 2.68 ± 0.01 | 5.1 ± 0.4 |
| | | | | to | |
| | | | | 2.82 ± 0.04 | |
| B | Damaged | 4.4° | n/a | 3.67 ± 0.07 | 3.0 ± 1.1 |
| | | | | to | |
| | | | | 4.13 ± 0.19 | |

*Interfacial water contact angles.
**n-PTMS reagent = 0.01 wt %. Acetic acid modifier = 0.01 wt %.
Δ Average values for all samples tested. Values are not corrected for measurement artifacts or relative sensitivity factor differences. Measurements made at room temperature.
ΔΔ Average carbon (peak C) content values, as measured by XPS, for all samples tested. Values are not corrected for measurement artifacts or relative sensitivity factor differences. Measurements made at room temperature.

Results show the damaged substrates 20 were repaired in conjunction the n-PTMS reagent and near-critical or supercritical CO₂ solvent fluid, restoring the contact angles and dielectric constants of the treated materials to near undamaged control values. Contact angles of the treated substrates 20 relative to undamaged controls were in the range from about 92.2% (Sample 1-1) to about 96.6% (Sample 1-5) of the undamaged control values following treatment, indicating successful hydrophobization of the damaged interface. Dielectric constants of the treated sample materials relative to the average damaged control values (k=3.9) were in the range from about 73.6% (Sample 1-3) to about 88.8% (Sample 1-1) following treatment. Carbon content values (measured as atomic %) were in the range from about 69% (Sample 1-2) to 141% (Sample 1-6) of the undamaged control values following treatment, revealing that carbon content can be effectively restored by this method. Further optimization of treatment conditions is expected to further improve results.

### EXAMPLE 2

Example 2 presents results for n-PTMS repair of damaged dielectric substrates in conjunction with use of a low-temperature repair and a high-temperature “bake” (cure), according to another embodiment of the invention. A dielectric substrate 20 damaged by, e.g., etch processing was introduced to reactor 10. Premixing vessel 40 was charged with ˜5 μL of reagent grade n-propyltrimethoxysilane (n-PTMS) (Gelest, Inc., Philadelphia, Pa.) and 10 μL H₂O to initiate polymerization and/or cross-linking of the n-PTMS reagent. Reactor 10 was pressurized with solvent fluid comprising carbon dioxide to a pressure of 2500 psig achieving a concentration for the n-PTMS reagent in the near-critical or supercritical solvent fluid of about 0.01 wt %, but is not limited thereto. A low operating temperature of reactor 10 for repair was selected in the range from about 25° C. to about 40° C., but is not limited thereto. In exemplary tests, substrates 20 were treated with n-PTMS at a (deposition) temperature of 25° C. Contact time with the reagent fluid was about 30 minutes, but is not limited thereto. Substrates 20 were subsequently “baked” (cured) at a temperature in the range from about 150° C. to about 200° C. to optimize cross-linking across damaged sites of the treated substrates, thereby strengthening the substrates and restoring the hydrophobicity. Table 2 lists contact angles, dielectric constants, and carbon (peak C) contents (as measured by XPS) for substrates 20 before and after treatment with n-PTMS reagent and associated high-temperature “bake”.

TABLE 2
Contact angles, dielectric constants, and carbon contents measured
before and following repair of dielectric substrates using a
low temperature deposition with n-propyltrimethoxysilane (n-PTMS)
followed by a high-temperature bake (cure).

| | | | | | Carbon |
|---|---|---|---|---|---|
| | | | | Dielectric | Content |
| | | Contact Angle*Δ | | Constant | (Atomic %) |
| | Treatment | Before | After | k Δ | ΔΔ |
| Samples | | | | | |
| 2-1 | n-PTMS; | 3.4° | 93.9 ± 1.71° | 2.74 ± 0.05 | 3.9 ± 0.4 |
| | 25° C.; | | | | |
| | 2500 psig; | | | | |
| | 175° C. bake; | | | | |
| 2-2 | n-PTMS; | 3.9° | 84.4 ± 6.96° | 2.82 ± 0.04 | 3.6 ± 0.8 |
| | 25° C.; | | | | |
| | 2500 psig; | | | | |
| | 150° C. bake | | | | |
| 2-3 | n-PTMS; | 3.8° | 81.9 ± 4.89° | 2.99 ± 0.06 | — |
| | 25° C.; | | | | |
| | 2500 psig; | | | | |
| | 200° C. bake | | | | |
| 2-4 | n-PTMS; | 4.2° | 92.8 ± 2.13° | 2.83 ± 0.05 | — |
| | 40° C.; | | | | |
| | 2500 psig; | | | | |
| | 150° C. bake | | | | |
| 2-5 | n-PTMS; | 4.4° | — | — | — |
| | 40° C.; | | | | |
| | 2500 psig; | | | | |
| | 175° C. bake | | | | |
| 2-6 | n-PTMS; | 4.5° | — | — | — |
| | 40° C.; | | | | |
| | 2500 psig; | | | | |
| | 200° C. bake | | | | |
| Controls | | | | | |
| A | Undamaged | 97.2° | n/a | 2.68 ± 0.01 | 5.1 ± 0.4 |
| | | | | to | |
| | | | | 2.82 ± 0.04 | |
| B | Damaged | 4.4° | n/a | 3.67 ± 0.07 | 3.0 ± 1.1 |
| | | | | to | |
| | | | | 4.13 ± 0.19 | |

*Interfacial water contact angles.
Δ Average values for all samples tested. Values are not corrected for measurement artifacts or relative sensitivity factor differences. Measurements made at room temperature.
ΔΔ Average carbon (peak C) content values, as measured by XPS, for all samples tested. Values are not corrected for measurement artifacts or relative sensitivity factor differences. Measurements made at room temperature.

Results again show low-k dielectric substrates 20 damaged during etch processing are modified and/or repaired using near-critical or supercritical CO₂ and alkoxysilanes such as n-propyltrimethoxysilane. Contact angles of the treated materials relative to undamaged control materials were in the range from about 84.3% (Sample 2-3) to about 96.6% (Sample 2-1) of the undamaged control values following treatment. Corresponding dielectric constants of the treated sample materials relative to the damaged control values were in the range from about 91.3% (Sample 2-1) to about 99.7% (Sample 2-3) of the undamaged control values following treatment. Carbon content values were in the range from about 71% (Sample 2-2) to 76% (Sample 2-1) of the undamaged control values following treatment. Further optimization of treatment conditions is expected to further improve results.

### EXAMPLE 3

Example 3 presents n-PTMS repair results for damaged dielectric substrates subjected to an initial pre-clean step. In exemplary tests, pre-clean solution was a dilute (1:1000) HF solution (HF:H₂O) prepared in deionized water. Substrates were immersed in the HF solution for about 60 seconds, rinsed in deionized water, and dried under nitrogen gas stream for about 60 seconds. In alternate tests, pre-clean solution was a surfactant solution, as described in co-pending application Ser. No. 10/851,380. State of repair was assessed by exposing substrates repaired in conjunction with n-PTMS to an HF etching (1:100 HF:H₂O) solution (“HF Dip”) for 60 seconds, rinsing in deionized water, and drying under nitrogen atmosphere. Evidence of etching and/or degree of etching was indicative of no repair or partial repair. Absence of etching was indicative of complete repair. Table 3 presents HF etch (“HF Dip”) test results (nm) listing average critical dimension changes measured for sets of from 8 to 10 vias of varying size (i.e., 250 nm, 500 nm, and 1 μm, respectively) present on the substrate. Critical dimension (e.g., width) and “undercutting” (side-wall) changes to pattern features (e.g., vias and trenches) were measured in conjunction with SEM analysis.

TABLE 3
Critical Dimension changes measured for 250 nm, 500 nm, and 1000 nm pattern vias of damaged dielectric
substrates following listed treatment regimens with n-PTMS (i.e., repair), dilute (1:1000) HF (i.e.,
pre-clean), and/or (1:100) HF etch (i.e., HF Dip), as compare with substrate controls.

| Treatment | | | | | | |
|---|---|---|---|---|---|---|
| [(protocol 1) − (protocol 2)] | 250 nm Via*Δ | | 500 nm Via*Δ | | 1000 nm Via*Δ | |
| Regular Volume** | | | | | | |
| (No HF Clean, n-PTMS Repair, HF | 93.7 ± 18.6 | nm | 97.3 ± 25.0 | nm | 133.3 ± 49.8 | nm |
| Dip) − (No HF Clean, No n-PTMS | | | | | | |
| Repair, No HF Dip) | | | | | | |
| (HF Clean, n-PTMS Repair, HF | 21.8 ± 24.5 | nm | 36.3 ± 27.7 | nm | 36.9 ± 35.5 | nm |
| Dip) − (No HF Clean, No n-PTMS | | | | | | |
| Repair, No HF Dip) | | | | | | |
| (Surfactant Clean, n-PTMS Repair, | 26.6 ± 7.5 | nm | 31.1 ± 23.0 | nm | 11.3 ± 27.1 | nm |
| HF Dip) − (No Surfactant Clean, | | | | | | |
| No n-PTMS Repair, No HF Dip) | | | | | | |
| Reduced Volume*** | | | | | | |
| (No HF Clean, n-PTMS Repair, HF | 67.5 ± 26.7 | nm | 40.6 ± 23.7 | nm | 76.3 ± 46.7 | nm |
| Dip) − (No HF Clean, No Repair, | | | | | | |
| No HF Dip) | | | | | | |
| (HF Clean, n-PTMS Repair, HF | 15.8 ± 22.6 | nm | 36.7 ± 23.5 | nm | 25.0 ± 42.2 | nm |
| Dip) − (No HF Clean, No n-PTMS | | | | | | |
| Repair, No HF Dip) | | | | | | |
| (Surfactant Clean, n-PTMS Repair, | 26.6 ± 7.5 | nm | 31.1 ± 23.0 | nm | 11.3 ± 27.1 | nm |
| HF Dip) − (No Surfactant Clean, | | | | | | |
| No n-PTMS Repair, No HF Dip) | | | | | | |
| HMDS | | | | | | |
| (No HF Clean, HMDS Repair, HF | 45.6 ± 13.4 | nm | 81.2 ± 22.2 | | 124.4 ± 34.9 | |
| Dip) − (No HF Clean, No HMDS | | | | | | |
| Repair, No HF Dip) | | | | | | |
| (HF Clean, HMDS Repair, HF Dip) − | 78.8 ± 19.1 | nm | 80.7 ± 28.9 | | 113.2 ± 37.3 | |
| (No HF Clean, No HMDS Repair, | | | | | | |
| No HF Dip) | | | | | | |
| Controls | | | | | | |
| (HF Clean, No n-PTMS Repair, No | 26.4 ± 19.4 | nmΔΔ | 22.3 ± 17.6 | nmΔΔ | 43.1 ± 40.4 | nmΔΔ |
| HF Dip) − (No HF Clean, No | | | | | | |
| n-PTMS Repair, No HF Dip) | | | | | | |
| (HF Clean (1:1000), n-PTMS | 144.2 ± 26.8 | nm⋄ | 159.5 ± 32.4 | nm⋄ | 204.8 ± 59.1 | nm⋄ |
| Repair, HF Dip (1:100)) − (No HF | | | | | | |
| Clean, No n-PTMS Repair, No HF | | | | | | |
| Dip) | | | | | | |

*Errors represent cumulative values from the averaqes of 8 to 10 vias measured.
ΔValues represent average net critical dimension or undercutting values for the set of 8 to 10 vias measured, i.e., values measured for treatment protocol 1 less values measured for treatment protocol 2, i.e., [(treatment 1) “−” (treatment 2)], respectively.
**Regular Volume = 50 μL n-PTMS reagent + 100 μL H₂O premixed in 5 mL premixing cell achieving about 0.1 wt % n-PTMS reagent concentration.
***Reduced Volume = 5 μL n-PTMS reagent + 10 μL H₂O premixed in 5 mL premixing cell achieving about 0.01 wt % n-PTMS reagent concentration.
ΔΔBest case control values. Comparable results are indicative of good repair.
⋄Worst case control values. Comparable results are indicative of poor repair.

Results show subjecting damaged dielectric substrates and/or materials to a pre-clean step with a cleaning solution, agent, and/or process improves the n-PTMS repair on some types of dielectric materials. Pre-cleaning on other types of materials does not enable repair.

### EXAMPLE 4

Example 4 presents n-PTMS repair results for damaged dielectric substrates comprising pattern structures (i.e., trenches) subjected to an initial pre-clean step. In exemplary tests, pre-clean solution was a dilute (1:1000) HF solution (HF:H₂O) prepared in deionized water. Substrates were immersed in the HF solution for about 60 seconds, rinsed in deionized water, and dried under nitrogen atmosphere for about 60 seconds. State of repair was assessed by exposing substrates repaired in conjunction with n-PTMS to an HF etching (1:100 HF:H₂O) solution (“HF Dip”) for 60 seconds, rinsing in deionized water, and drying under nitrogen atmosphere. Evidence of etching and/or degree of etching was indicative of no repair or partial repair. Absence of etching was indicative of complete repair. Table 4 presents HF etch (“HF Dip”) test results listing average critical dimension changes measured for sets of from 8 to 10 (300 nm-400 nm) pattern features (e.g., trenches) of the substrate. Critical dimension (e.g., width) and “undercutting” (side-wall) changes to pattern features were measured in conjunction with SEM analysis.

TABLE 4
Critical Dimension or Undercutting changes measured for (300-400
nm) pattern trenches of damaged dielectric substrates following
listed treatment regimens with n-PTMS (i.e., repair), dilute
(1:1000) HF (i.e., pre-clean), and/or (1:100) HF etch (“HF
Dip”), as compare with substrate controls.

| | Critical Dimension | Undercutting |
|---|---|---|
| Treatment | changes | changes |
| [(protocol 1) − | 300-400 nm | 300-400 nm |
| (protocol 2)] | Trench*Δ | Trench*Δ |
| Samples | | |
| (No HF Clean, n-PTMS Repair, | 39.6 ± 7.5 nm | 28.9 ± 4.3 nm |
| HF Dip) − (No HF Clean, | | |
| No n-PTMS Repair, No HF Dip) | | |
| (HF Clean, Repair, HF Dip) − | 19.4 ± 8.2 nm | 19.2 ± 4.2 nm |
| (No HF Clean, No | | |
| n-PTMS Repair, No HF Dip) | | |
| Controls | | |
| (HF Clean, No n-PTMS Repair, | 7.7 ± 5.1 nmΔΔ | 1.4 ± 4.6 nmΔΔ |
| No HF Dip) - (No HF Clean, | | |
| No n-PTMS Repair, No HF Dip) | | |
| (No HF Clean, No n-PTMS | 67.6 ± 9.1 nm | 26.5 ± 4.7 nm |
| Repair, HF Dip) - (No HF | | |
| Clean, No Repair, No HF Dip) | | |
| (HF Clean, No n-PTMS Repair, | 89.6 ± 6.5 nm⋄ | 47.0 ± 5.4 nm⋄ |
| HF Dip) - (No HF Clean, | | |
| No n-PTMS Repair, No HF Dip) | | |

*Errors represent cumulative values for the set of 8 to 10 trenches measured.
ΔValues represent average net critical dimension or undercutting values for the set of 8 to 10 trenches measured, i.e., values for treatment protocol 1 less values for treatment protocol 2, i.e., [(treatment 1) “−” (treatment 2)], respectively.
ΔΔBest case control values. Comparable results are indicative of good repair.
⋄Worst case control values. Comparable results are indicative of poor repair.

Results for damaged dielectrics with trench feature patterns show repair values of between about 45% and about 75% of the undamaged controls. Further work is expected to further optimize results.

While the preferred embodiments of the present invention have been shown and described, it will be apparent to those skilled in the art that many changes and modifications may be made without departing from the invention in its true scope and broader aspects. The appended claims are therefore intended to cover all such changes and modifications as fall within the spirit and scope of the invention.

We claim:

1. A process for modifying or repairing a dielectric material, comprising:
contacting a dielectric material having damage sites with a near-critical or supercritical fluid comprising alkoxysilane silylating agent whereby said damage sites are modified substantially repairing said sites contacted by said agent.

2. The process of claim 1, wherein said dielectric material is a low-k dielectric material selected from the group consisting of inorganic dielectrics, organic dielectrics, hybrid dielectrics, interlayer dielectrics, spin-on dielectrics, or combinations thereof.

3. The process of claim 1, wherein said repairing comprises chemically capping terminal hydroxyl(—OH) functional group(s) by action of said alkoxysilane silylating agent comprising hydrophobic alkyl groups substantially restoring hydrophobicity of said material.

4. The process of claim 1, wherein said repairing comprises chemically capping terminal hydroxyl(—OH) functional groups with said alkoxysilane silylating agent substantially restoring the dielectric value of said material and whereby cross-linking of said silylating agent substantially restores the structural integrity of said material.

5. The process of claim 4, wherein said dielectric value of said material is restored to a value less than about 3.2.

6. The process of claim 4, wherein said cross-linking yields a Young's modulus value for said material of greater than or equal to about 14.3 MPa.

7. The process of claim 1, wherein said repairing comprises substantially restoring the hydrophobicity of said material by substantially restoring the interfacial contact angle of said material.

8. The process of claim 7, wherein said interfacial contact angle is in the range from about 80 degrees to about 95 degrees, or better.

9. The process of claim 1, wherein said repairing further comprises substantially restoring the carbon content of said material.

10. The process of claim 9, wherein said carbon content is increased to a value in the range of from about 3% to about 15% (mole-fraction basis).

11. The process of claim 1, wherein said alkoxysilane silylating agent is selected from the group consisting of n-propyltrimethoxysilane, n-propyltriethoxysilane, ethyltrimethoxysilane, ethyltriethoxysilane, methyltrimethoxysilane, methyltriethoxysilane, dimethyldimethoxysilane, derivatives thereof, or combinations thereof.

12. The process of claim 1, wherein said near-critical, or supercritical fluid comprises a member selected from the group consisting of Freon®, carbon dioxide, noble gases, nitrogen, unsaturated aliphatic hydrocarbons, alkanes, carboxylic acids, sulfurhexafluoride, ammonia, alcohols, methyl amines, derivatives thereof, or combinations thereof.

13. The process of claim 1, wherein said fluid has a density above the critical density for said fluid.

14. The process of claim 1, wherein said fluid comprises carbon dioxide at a pressure in the range from about 800 psi to about 8000 psi and a temperature in the range from about −40° C. to about 300° C.

15. The process of claim 1, wherein said fluid further comprises a modifier reagent.

16. The process of claim 15, wherein said modifier reagent is a carboxylic acid selected from the group consisting of formic acid and/or acetic acid.

17. The process of claim 1, wherein said dielectric material is pre-cleaned prior to contacting with said alkoxysilane silylating agent in said near-critical or supercritical fluid.

18. A process, comprising:
providing a dielectric material having sites characterized by hydrophilic damage;
providing a near-critical or supercritical fluid comprising an alkoxysilane silylating agent; and
contacting said material with said fluid, whereby said sites are rendered hydrophobic substantially repairing said hydrophilic damage of said material.

19. The process of Claim 18, wherein said alkoxysilane silylating agent is selected from the group consisting of n-propyltrimethoxysilane, n-propyltriethoxysilane, ethyltrimethoxysilane, ethyltriethoxysilane, methyltrimethoxysilane, methyltriethoxysilane, or combinations thereof.

20. The process of claim 18, wherein said near-critical, or supercritical fluid is selected from the group consisting of Freon®, carbon dioxide, noble gases, nitrogen, unsaturated aliphatic hydrocarbons, alkanes carboxylic acids, sulfurhexafluoride, ammonia, alcohols, methyl amines, derivatives thereof, or combinations thereof.

21. The process of claim 18, wherein repairing comprises capping of said hydrophilic damage sites comprising terminal hydroxyl(—OH) functional groups by action of said alkoxysilane silylating agent.

22. The process of claim 18, wherein repairing further comprises cross-linking of said material by action of said alkoxysilane silylating agent substantially restoring the structural integrity of said material.

23. The process claim 21, wherein said structural integrity comprises a Young's modulus value of greater than about 14.3 MPa.

24. The process of claim 21, wherein repairing achieves a dielectric value for said material of less than about 3.2.

25. The process of claim 18, wherein repairing comprises an increase in interfacial water contact angle of said material to a value in the range from about 80 degrees to about 95 degrees or better.

26. The process of claim 18, wherein said repairing further comprises substantially restoring the carbon content of said material.

27. The process of claim 18, wherein said carbon content of said material is increased by a value in the range of from about 3% to about 15% (mole-fraction basis).

28. The process of claim 18, wherein the fluid density is above the critical density for the fluid.

29. The process of claim 18, wherein said carbon dioxide has a pressure in the range from about 800 psi to about 8000 psi and a temperature in the range from about −40° C. to about 300° C.

30. The process of claim 18, wherein said fluid further comprises a modifier reagent.

31. The process of claim 30, wherein said modifier reagent is a carboxylic acid selected from the group consisting of formic acid and/or acetic acid.

32. The process of claim 18, wherein said dielectric material is pre-cleaned prior to contacting with said alkoxysilane silylating agent in said near-critical or supercritical fluid.
